(19) United States
(12) Patent Application Publication
(10) Pub. No.: US 2013/0160700 A1
(43) Pub. Date: Jun. 27, 2013

(54) STEP HEATING PROCESS FOR GROWING HIGH QUALITY DIAMOND

(71) Applicants: Joo Ro KIM, Bradenton, FL (US); Hexiang ZHU, Bradenton, FL (US); Karl PEARSON, Bradenton, FL (US)

(72) Inventors: Joo Ro KIM, Bradenton, FL (US); Hexiang ZHU, Bradenton, FL (US); Karl PEARSON, Bradenton, FL (US)

(73) Assignee: GEMESIS DIAMOND COMPANY, Sarasota, FL (US)

(21) Appl. No.: 13/332,636

(22) Filed: Dec. 21, 2011

(51) Int. Cl. C30B 9/00

(52) U.S. Cl. 117/79

(57) ABSTRACT

Disclosed is a method of growing a diamond, including the steps of providing a diamond seed in a reaction chamber; providing a protective layer above the diamond seed; providing a catalyst above the protective layer; providing a carbon source above the catalyst; applying pressure to the reaction chamber; heating the catalyst to a first temperature; holding the first temperature for a first duration; heating the catalyst to a second temperature; and holding the second temperature for a second duration.

### BACKGROUND OF THE INVENTION

1. Field of the Invention

The present subject matter relates generally to an apparatus and method for growing a diamond, and more specifically to an apparatus and method for growing a diamond using a step heating process.

2. Related Art

The synthesis of diamond crystals by high temperature, high pressure processes via a temperature gradient method was established by the General Electric Company as described in U.S. Pat. No. 4,034,066. As a result of subsequent large-scale production by Sumitomo Electric Industries, Ltd., as described in U.S. Pat. No. 4,836,881, diamonds synthesized by this method are commercially available as heat sinks, super-precision cutting tools, and other fabricated products. The diamond growth process using a high temperature, high pressure apparatus can include a reaction cell which contains (a) graphite as a carbon source, (b) a diamond seed crystal, and (c) a solvent metal which separates the carbon source from the seed crystal.

A temperature gradient between the carbon source and seed crystal can create a carbon solubility difference, resulting that the carbon atoms are dissolved from the carbon source into the solvent metal upon heating and precipitated on a diamond seed. The temperature and pressure are such as to permit diamond crystal growth on the seed crystal.

During growth of diamond crystals, the carbon source dissolves into the solvent metal upon heating, and a temperature gradient exists between the carbon source and seed crystal. By very carefully adjusting pressure and temperature and utilizing a small temperature gradient over extended growth times, larger diamonds can be produced. However, attempts to increase crystal sizes have shown a strong tendency for spontaneous nucleation of diamond crystals to occur at the underside of the molten catalyst-solvent metal. This develops into a serious problem, because the diamond nucleation occurring near the seed diamond competes with the growth from the seed diamond, resulting in the development of multiple crystals which collide as they grow. In addition, the seed diamond may be dissolved if the metal solvent composition is improper, resulting in no growth from the seed crystal at all.

Numerous attempts to increase the quality and yield have been failed, at least partially due to a high tendency for the spontaneous multi-diamond crystal nucleation and seed diamond dissolution. The prior art for growth of diamonds (U.S. Pat. Nos. 6,030,595; 6,129,900; 4,836,881; 4,034,066; 4,042,673; 4,073,380; and 4,322,396) has included the use of a single layer metal catalyst which provides a fixed composition of carbon in a metallic catalyst. An issue with the prior art is that the high quality single diamond crystal growth is limited without the precise control temperature and/or pressure. If the temperature is too high and/or the pressure is too low, the carbon solubility of a metallic catalyst increases and the seed diamond is dissolved with no diamond crystal growth. If the temperature is too low and/or the pressure is too high, decrease of the carbon solubility can result in carbon oversaturation near the seed diamond region, which increases the possibility of spontaneous nucleation. The reason why two opposite problems can occur even with a fixed carbon composition in the metallic catalyst is the relatively large operation window of the pressure and temperature in the high pressure circumstance. Therefore the pressure/temperature window for a high-quality diamond crystals via using a single-layer metal catalyst in the prior art is limited. Accordingly, an improved process for high quality diamond crystal growth for commercial HPHT diamond production is desired.

### SUMMARY OF THE INVENTION

One of the distinctive aspects of the presently claimed subject matter is a method for growing high quality diamond. The method includes the steps of providing a diamond seed in a reaction chamber and providing a protective layer above the diamond seed. A catalyst is provided above the protective layer, and a carbon source is provided above the catalyst. Pressure is applied to the reaction chamber and the catalyst is heated to a first temperature and held at the first temperature for a first duration. In another step, the catalyst is then heated to a second temperature. In another step, the catalyst is held at the second temperature for a second duration.

According to an aspect of the subject matter, the method includes holding the first temperature until the catalyst is at least partially melted and saturated with carbon.

According to another aspect of the subject matter, the first temperature is between a melting point of the catalyst and a melting point of the protective layer.

According to a further aspect of the subject matter, the second duration exceeds the first duration, and in certain aspects, the second temperature exceeds the first temperature.

According to a further aspect of the subject matter, the protective layer is a metal foil. In certain aspects, the metal foil contains copper.

According to a further aspect of the subject matter, the carbon source is at least partially comprised of graphite.

According to another aspect of the subject matter, the percentage of spontaneous nucleation is between approximately 3% and 28%.

According to a further aspect of the subject matter, the pressure is between approximately 5.5 and 6.5 GPa, the first temperature is between approximately 1150 and 1200° C., the first duration is approximately two hours, the second temperature is between approximately 1300 and 1400° C., and the second duration is between approximately 90 and 120 hours.

### BRIEF DESCRIPTION OF THE DRAWINGS

These and other aspects of the subject matter will be apparent with reference to the examples in the following description and with reference to the accompanying drawings, the description not meaning to be considered limiting in any matter, wherein:

FIG. 1 shows a vertical cross-section view of an embodiment of the present subject matter;

FIG. 2 shows a related-art carbon equilibrium phase diagram showing the region where diamond grows using metal catalyst solvents in high pressure high temperature (HPHT) diamond synthesis (Department of Chemistry Website, University of Bristol, U.K.);

FIG. 3 shows a three-dimensional view of the large and small dies, the core area, and gaps between the dies for the flow of cooling water;

FIG. 4 shows a typical picture of a spontaneous nucleation around a central diamond;

FIG. 5 shows a typical picture of diamond seed dissolution;

FIG. 6 shows a picture of a crystal diamond without spontaneous nucleation or diamond seed dissolution;

FIG. 7 shows a schematic of an exemplary structure according to an embodiment of the present subject matter;

FIG. 8A shows a graph of supplied power over time in an exemplary step heating process in accordance with the present subject matter; and

FIG. 8B shows a graph of temperature vs. power in an exemplary step heating process in accordance with the present subject matter.

### DETAILED DESCRIPTION OF THE DRAWINGS

The figures are diagrammatic and not drawn to scale. In the figures, elements which correspond to elements already described have the same reference numerals.

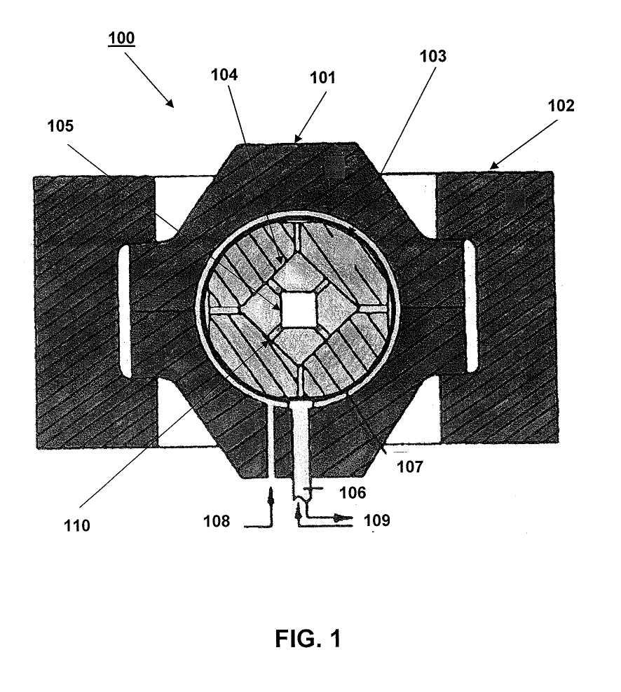

FIG. 1 shows a vertical cross-section view of an embodiment of the present subject matter. In FIG. 1, a split-sphere high pressure, high temperature (HPHT) apparatus 100 includes a split-sphere growth chamber 101 and a plurality of safety clamps 102 on opposite sides of the growth chamber 101. The growth chamber 101 comprises a top half and a bottom half, with a cavity defined therein. Large dies 103, small dies 104, and a reaction cell 105 are positioned in the cavity. Between the inner surface of the growth chamber 101 and the large dies 103 is provided a rubber membrane (or diaphragm) 107.

In operation of the HPHT apparatus 100, as the top and bottom halves of the growth chamber 101 are brought together, pressure is applied to the large dies 103, which in turn apply pressure to the small dies 104. As pressure is applied to the small dies 104, the dies apply pressure to the reaction cell 105. Prior to being placed in the growth chamber 101, the reaction cell 105 is charged with a carbon source, a diamond seed, and a metal solvent/catalyst mixture used to produce a diamond. Carbon sources, diamond seeds and solvent/metal catalysts are generally known in the art, and any such material is appropriate for use in the apparatus of the present subject matter.

The HPHT apparatus 100 also contains at least one manifold 108 though which cooling water 109 can access the cavity of the growth chamber 101 from outside of the apparatus 100, and the cooling water 109 can access in opposite direction. In the embodiment depicted in FIG. 1, a two-way manifold 106 allows a user to either draw gases and other substances out of the growth chamber 101 or introduce different gases or material into the growth chamber 101. For example, a user can remove impurities from the growth chamber 101. Alternatively, the flow can be reversed to introduce an inert gas or some other desired gas into the growth chamber 101 by way of the two-way manifold 106. An advantage to using a two-way manifold rather than multiple inlets is that the number of locations where the chamber is exposed to contamination is kept to a minimum, thereby ensuring that the inside of the reaction cell 105 and the split sphere chamber 101 can be kept under adequate control.

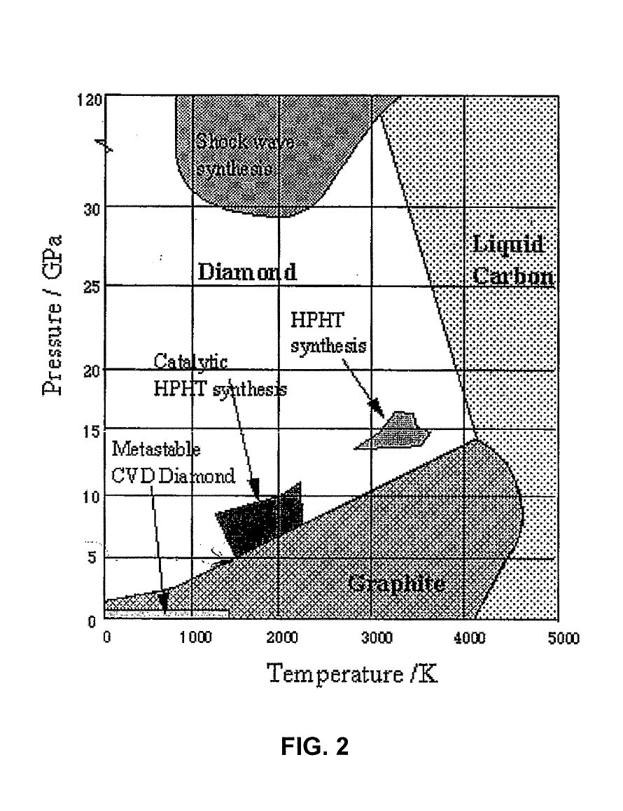

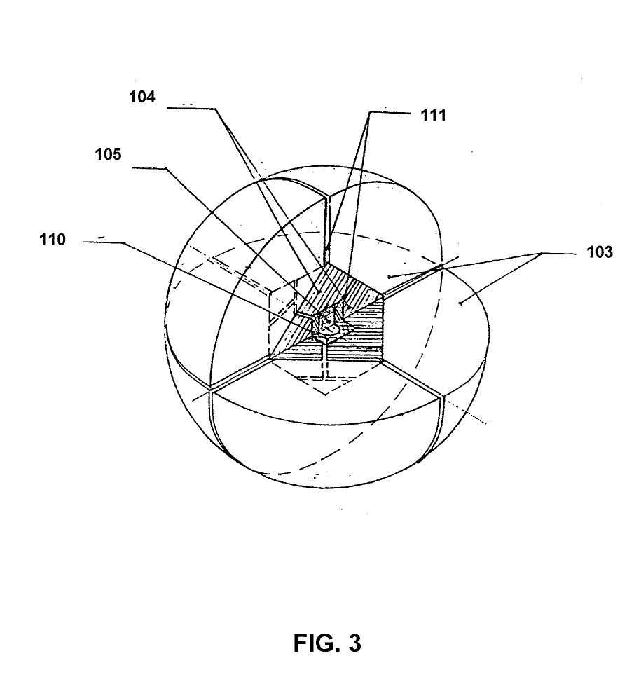

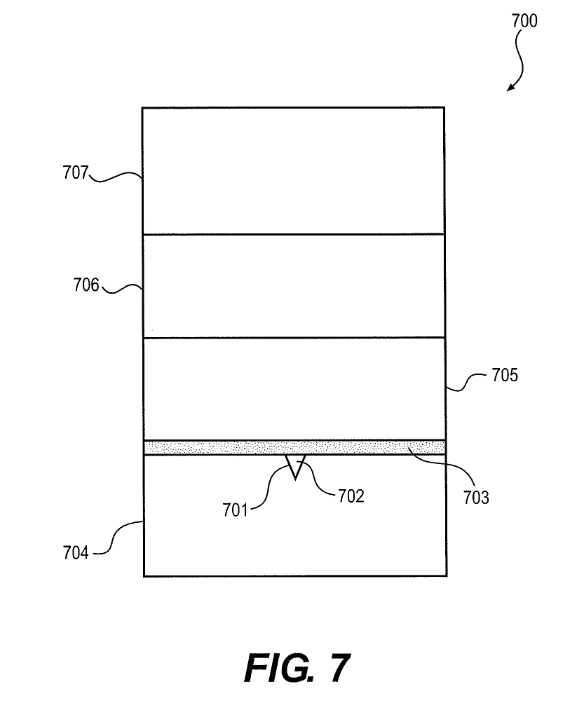

In the HPHT apparatus 100 disclosed in FIG. 1, the reaction cell 105 is configured to contain a diamond seed crystal 702, a carbon source 706, and a catalyst 705 provided between a protective layer 703 and the carbon source 706 (reference numerals referring to FIG. 7). Crystal growth is caused by extremely high isostatic pressures (i.e., equal from all sides) and a temperature gradient due to heating in the reaction cell 105 where the maximum temperature is located at the carbon source 706 and the minimum temperature at the seed crystal 702. The temperatures and pressures in the reaction cell 105 are in the diamond stable region of the carbon phase diagram as shown in FIG. 2. The pressure created at the core surface is based on the geometry of the dies 103, 104, or more specifically, the decrease in the surface area or interaction area between the rubber membrane 107 and the large die 103 in contrast to the interface area between the small dies 104 and the reaction cell 105. The relationship of the large and small dies 103, 104 as well as the reduction in surface area is shown in FIG. 3. The three-dimensional view in FIG. 3 also shows the gaps 111 between the dies 103, 104 for allowing cooling water to flow through the system. This design allows the pressure at the rubber membrane to be relatively small yet create ultra high isostatic pressure at the core cell (reaction chamber) 105.

One of skill in the art of high pressure, high temperature apparatuses will appreciate that the embodiments described above are in relation to a split-sphere high pressure, high temperature apparatus. However, the embodiment described above is for illustrative purposes and should not be construed as limiting the inventive subject matter to use only in split-sphere high pressure, high temperature apparatuses.

Other high pressure, high temperature apparatuses are also usable in the present inventive subject matter. Examples of other high pressure, high temperature apparatuses include, without limitation, a belt-type apparatus, a piston-cylinder apparatus, an annular-die apparatus and a toroid apparatus. Each type of high pressure, high temperature apparatus is well-known in the art. For example, U.S. Pat. No. 4,301,134 to Strong describes a belt-type high pressure, high temperature apparatus usable in the present inventive subject matter, while U.S. Pat. No. 5,244,368 to Frushour describes a non-limiting example of a piston-cylinder high pressure, high temperature apparatus that is also usable in the present inventive subject matter. Likewise, U.S. Pat. No. 4,518,334 describes an annular-die high pressure, high temperature apparatus employable in the present inventive subject matter. Further, U.S. Pat. No. 4,290,741 to Kolchin et al. and U.S. Patent Application Publication No. 2004/0134415 to D'Evelyn et al. disclose toroid high pressure, high temperature apparatuses that are usable in the present inventive subject matter. The contents of each of the above-listed U.S. patents and published patent applications are hereby incorporated in their entirety.

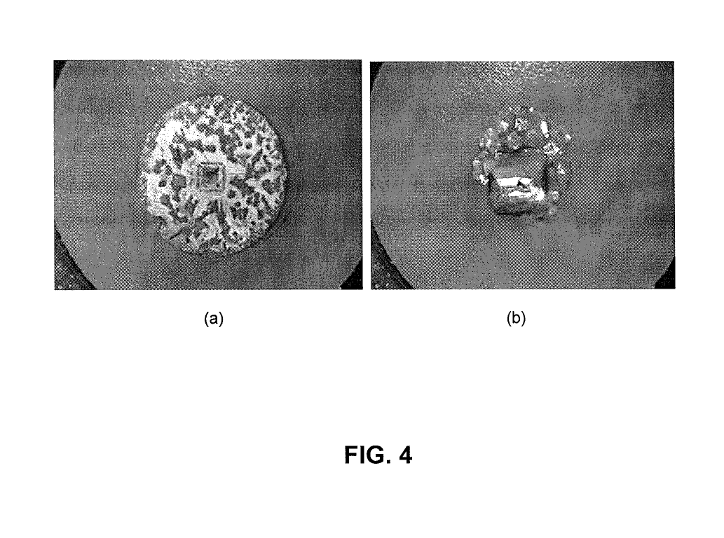

FIG. 4 shows a typical picture of a spontaneous nucleation around a central diamond. In low temperature and/or high pressure (for example, 1300° C. and/or 6.0 GPa), multi-crystals can be nucleated due to an excess carbon amount, as shown in FIG. 4. Spontaneous nucleation often occurs at the underside of a metallic catalyst, because the carbon concentration near the seed exceeds its solubility limit, resulting in the spontaneous nucleation. Those nucleated diamond crystals compete with the growth from the seed diamond and this leads to the development of multiple crystals which collide as they grow, resulting in a poor quality of diamond crystal.

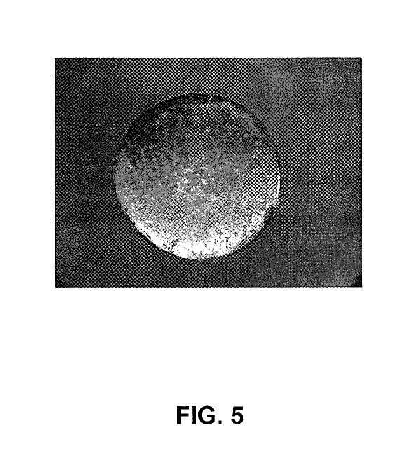

FIG. 5 shows a typical picture of diamond seed dissolution. In a high temperature and/or low pressure (for example, 1400° C. and/or 5.5 GPa), a diamond seed can be dissolved completely by deficiency of the carbon amount. This results at least in part from an insufficient carbon amount in the metallic catalyst, resulting in no growth from the seed diamond or, as shown in this figure, dissolution of the diamond seed.

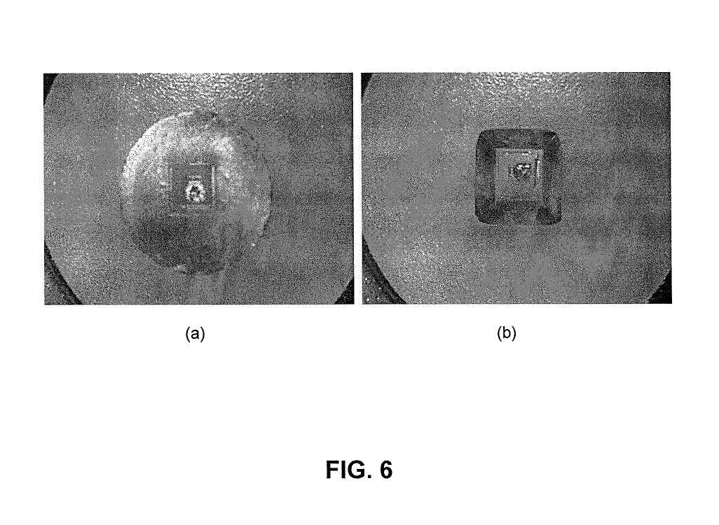

FIG. 6 shows a picture of a crystal diamond without spontaneous nucleation or diamond seed dissolution grown according to the present subject matter. As can be seen, spontaneous nucleation around the central diamond that is typically witnessed in other growth processes is remarkably reduced using a process according to the present subject matter.

FIG. 7 shows a schematic of an exemplary structure 700 according to an embodiment of the present subject matter. In the exemplary embodiment shown, on one surface of a ceramic seed pad 701 a recess is produced to accommodate a diamond seed 702 therein. A protective layer 703 is deposited on the surface of the seed pad 701. The protective layer 703 can be a metal foil, and in certain embodiments the foil contains copper (Cu). An additional ceramic layer 704 can be included underneath the seed pad 701 if desired. A catalyst 705 is deposited on a surface of the protective layer 703. In certain embodiments, the catalyst 705 can be a metallic disc which helps facilitate the diamond growth process. In other embodiments the catalyst can be non-metallic. In the figure shown, a carbon source 706 is deposited on a surface of the disc 705. Carbon source 706 can be any source of carbon, such as graphite or other carbon sources known to those of skill in the art, without departing from the scope of the present subject matter. A ceramic layer 707 can optionally be included on top of the carbon source 706. In an embodiment of the present disclosure, the metal disc catalyst 705 is made from an iron-nickel (Fe−Ni) alloy with the nickel being present in a concentration from about 0% to about 90% by weight. In this embodiment, the carbon concentration is between about 1.0% and about 7.0% by weight of the catalyst composition. In another embodiment of the present disclosure, the metal disc catalyst 705 is made from an iron-nickel (Fe-Ni) alloy with the nickel being present in a concentration from about 0% to about 90% by weight and the carbon is present in a concentration from about 2.0% to about 9.0% by weight.

As shown in FIG. 7, protective layer 703 (a copper foil in this exemplary embodiment) is located above the diamond seed 702, with catalyst 705 (as a metallic disc in this exemplary embodiment) stacked above the protective layer 703. The melting temperature of protective layer 703 is higher than that of the catalyst 705. Although only a single catalyst is used in this exemplary embodiment, multi-layer metals as solvent catalyst can also be used without departing from the scope of the present subject matter. The structure shown is exemplary only. Other structures can be employed without departing from the scope of the present subject matter.

In the embodiment of FIG. 7, protective layer 703 is selected such that it does not completely dissolve even if disc 705 is heated to the point that the disc is at least partially molten. In this embodiment, the disc is heated to a holding temperature between 1150-1200° C. such that disc 705 is fully molten. This temperature is between the melting point of the protective layer 703 and disc 705. The metallic catalyst (disc 705) will melt, but the copper foil (protective layer 703) remains at least partially solid, which protects the diamond seed 702. In the exemplary embodiment shown, the melted catalyst dissolves carbon from the carbon source 706 until the melted catalyst is saturated with carbon at the holding temperature.

Then, the diamond growth cell is slowly heated up to a second temperature at a rate between 5 and 15° C./min. Other heating rates can be used without departing from the scope of this subject matter. In this exemplary embodiment, the second temperature is between 1300 and 1400° C. At this temperature the protective layer 703 will melt and be dissolved by the molten catalyst, exposing the seed diamond to the molten catalyst. Since the carbon concentration in the molten catalyst has reached an equilibrium or near-equilibrium state, spontaneous nucleation and seed diamond dissolution is reduced or even prevented, regardless of variation in pressure and/or temperature. Thus, an excess or deficiency of carbon can be avoided regardless of the carbon composition in the catalyst.

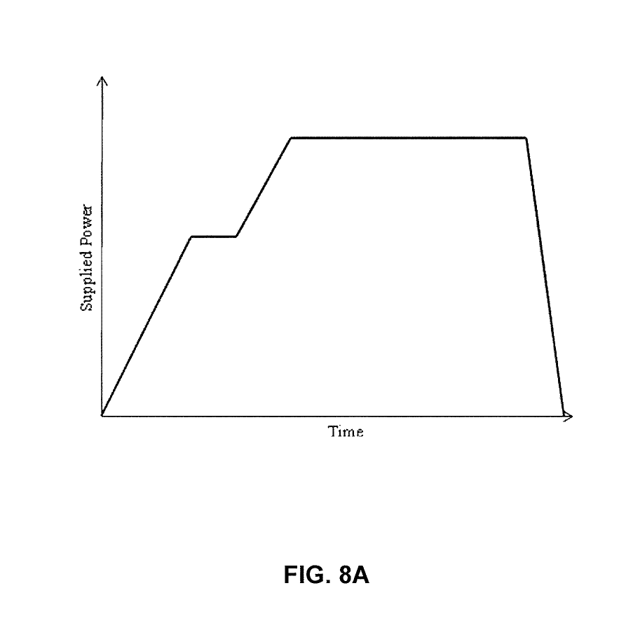

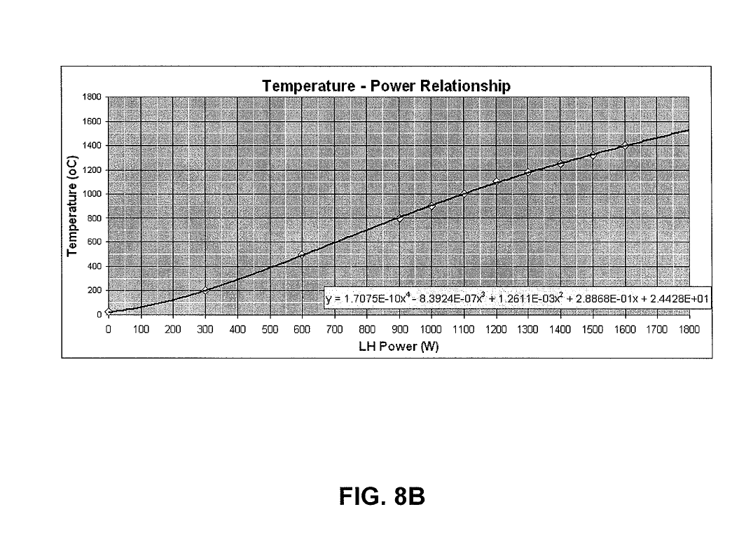

FIG. 8A shows a graph of supplied power over time in an exemplary step heating process in accordance with the present subject matter, and FIG. 8B shows a graph of temperature vs. power in an exemplary step heating process in accordance with the present subject matter. As shown in FIG. 8B, for example, 1300 watts corresponds to a temperature of approximately 1175° C., and 1550 watts corresponds to a temperature of approximately 1350° C. If applied power is held approximately constant, temperature in the reaction remains approximately constant as well. This process provides a wider temperature and pressure operation window for diamond growth without seed dissolution and/or spontaneous nucleation. In FIG. 8A, the first plateau of the power curve indicates a holding temperature in the growth cell for a desired time. The holding time shown is between one and five hours, but can be a different duration without departing from the scope of the present subject matter. The exemplary step heating curve shown in FIG. 8A takes three hours to reach full power, including a two-hour holding period at 1300 watts, which corresponds to a temperature between approximately 1150 and 1200° C. The total running cycle time for this exemplary step heating process is approximately 94 hours. Although outside pressure and power are held constant, pressure and temperature at the diamond growth region will fluctuate from run to run due to process variables. In the example shown, temperature varies from 1300 to 1400° C. at a constant power of 1550W, while the pressure varies from approximately 5.5 to 6.0 GPa, with machine pressure maintained at approximately 2280 Bar.

The step heating process in this disclosure is unique and provides an efficient technique which allows a precise control of diamond crystal growth. It is applicable to any diamond growth cell design if the melting point of the protective layer exceeds than that of the catalyst. The detailed conditions used in this particular step heating process are as follows:
Heating temperature: 1100-1500° C.;
Supplied power: 1400-1800W;
Pressure: 5.5-6.5 Gpa; and
Cycle time: 90-120 hrs.

Experimental results comparing a no step heating process with an exemplary two step heating process are shown on Table 1 below. As shown in Table I, the exemplary step heating process shown substantially reduce the spontaneous nucleation from 28% to 3%.

TABLE 1

| | No step heating | Two step heating |
|---|---|---|
| Content | process | process |
| Carbon composition in metallic | 4.5 wt % | 4.5 wt % |
| catalyst | | |
| % Grade 1, 2 | 52% | 72.4% |
| % Spontaneous nucleation | 28% | 3% |
| Total runs | 44 | 1230 |

Still other exemplary step heating processes may include the following additional conditions detailed below.
Ceramic caps (press media and heat insulator) (OD×L): 17.30×3.10 mm;
Top ceramic disc (OD×L): 12.10×6.80 mm;
Graphite rod (electrical lead for second independent heater) (OD×L): 1.10×3.60 mm;
Graphite disc or tube (diamond source) (OD×L): 12.10×4.00 mm;
CsCl sleeve (protector) (OD×ID×L): 17.25×15.25×24.00 mm;
Metal solvent (OD×L): 12.10×7.00 mm;
Protective layer (protecting seed dissolution) (OD×L): 12.10×0.10 mm;
Diamond seed: 30 Mesh;
Seed pad (OD×L): 12.10×6.40 mm;
Container (press media and heat insulator; a rectangular with a hole) (Width1×Width 2×L×ID): 24.20×24.20×30.50×17.40 mm; and
Material for metal catalyst: Fe—Ni alloy.

Although the subject matter has been described with reference to the illustrated embodiments, the subject matter is not limited thereto. The subject matter being thus described, it will be obvious that the same may be varied in many ways. Such variations are not to be regarded as a departure from the spirit and scope of the subject matter, and all such modifications as would be obvious to one skilled in the art are intended to be included within the scope of the following claims.

1. A method of growing a diamond, comprising:
providing a diamond seed;
providing a protective layer above the diamond seed;
providing a catalyst above the protective layer;
providing a carbon source above the catalyst;
applying pressure to the diamond seed, protective layer, catalyst, and carbon source;
heating the catalyst to a first temperature;
holding the first temperature for a first duration of approximately two hours;
heating the catalyst to a second temperature; and
holding the catalyst at the second temperature for a second duration between approximately 90 and 120 hours.

2. The method of claim 1, further comprising the step of holding the first temperature until the molten catalyst reaches an equilibrium state.

3. The method of claim 1, further comprising the step of holding the first temperature until the catalyst is saturated with carbon.

4. The method of claim 1, wherein the first temperature is between a melting point of the catalyst and a melting point of the protective layer.

5. The method of claim 1, wherein the second temperature exceeds the first temperature.

6. The method of claim 5, wherein the second duration exceeds the first duration.

7. The method of claim 1, wherein the protective layer is a metal foil.

8. The method of claim 7, wherein the metal is at least partially comprised of copper.

9. The method of claim 1, wherein the carbon source is at least partially comprised of graphite.

10. The method of claim 1, wherein a percentage of spontaneous nucleation is between approximately 3% and 28%.

11. The method of claim 1, wherein:
the pressure is between approximately 5.5 and 6.5 GPa;
the first temperature is between approximately 1150 and 1200° C.;
the second temperature is between approximately 1300 and 1400° C.

12. A method of growing a diamond, comprising:
providing a diamond seed in a reaction cell;
providing a protective layer above the diamond seed;
providing a catalyst above the protective layer;
providing a carbon source above the catalyst;
applying pressure to the reaction cell;
heating the catalyst to a first temperature;
holding the first temperature for a first duration of approximately two hours;
heating the catalyst to a second temperature; and
holding the second temperature for a second duration that is between 90 and 120 hours.
